(19) United States
(12) Patent Application Publication
(10) Pub. No.: US 2019/0189631 A1
(43) Pub. Date: Jun. 20, 2019

(54) COMPOSITION FOR ETCHING AND MANUFACTURING METHOD OF SEMICONDUCTOR DEVICE USING THE SAME

(71) Applicant: SOULBRAIN CO., LTD., Seongnam-si (KR)

(72) Inventors: Jin Uk LEE, Seongnam-si (KR); Jae Wan PARK, Seongnam-si (KR); Jung Hun LIM, Seongnam-si (KR)

(21) Appl. No.: 16/217,049

(22) Filed: Dec. 12, 2018

(30) Foreign Application Priority Data
Dec. 15, 2017 (KR) 10-2017-0173245
Dec. 4, 2018 (KR) 10-2018-0154369

(51) Int. Cl. H01L 27/11556; H01L 21/311; H01L 21/02; C23F 1/16; C09K 13/04

(52) U.S. Cl. CPC H01L 27/11556; H01L 21/31116; C09K 13/04; C23F 1/16; H01L 21/0217

(57) ABSTRACT

The present invention provides a composition for etching a silicon nitride film and a manufacturing method of a semiconductor device using the same, wherein the composition for etching a silicon nitride film comprises phosphoric acid, metaphosphoric acid, an ammonium salt-based compound, and water.

### CROSS-REFERENCE TO RELATED APPLICATIONS

This application claims priority under 35 U.S.C. § 119 to Korean Patent Application No. 10-2017-0173245, filed on Dec. 15, 2017, and Korean Patent Application No. 10-2018-0154369, filed on Dec. 4, 2018, in the Korean Intellectual Property Office, the disclosure of which is incorporated herein by reference in its entirety.

### TECHNICAL FIELD

The following disclosure relates to a composition for etching with a high selectivity and a manufacturing method of a semiconductor device through application of the composition for etching to an etching process.

### BACKGROUND

In semiconductor devices, oxide films such as silicon oxide films (SiO₂), and the like, and nitride films such as silicon nitride films (SiNₓ), and the like, are typical insulating films, each having a structure in which a single layer, or one or more layers of films, are alternately stacked. These oxide films and nitride films are also employed as a hard mask for forming conductive patterns such as metal wiring, and the like.

In the wet etching process for removing nitride films, a composition for etching in which phosphoric acid and deionized water are mixed is generally employed. Here, the deionized water is added to reduce the etching rate and prevent change of the etch selectivity with respect to the oxide film, but there is a problem in that defects occur due to minute changes in the amount of deionized water when nitride film is removed through the wet etching process. In addition, there is a limit in etching nitride films to a required level due to a decrease in the etch selectivity of the nitride film with respect to the oxide film. For example, in the device isolation process of flash memory devices, the nitride and oxide films are subjected to etching, and the problems which occur at this time are described in detail as follows with reference to FIGS. 1 and 2.

Referring to FIG. 1, a tunnel oxide film 11, a polysilicon film 12, a buffer oxide film 13, and a pad nitride film 14 are sequentially formed on a substrate 10, and then the polysilicon film 12, the buffer oxide film 13, and the pad nitride film 14 are selectively etched to form a trench. Subsequently, a spin on dielectric (SOD) oxide film 15 is formed until gap filling of the trench is achieved, and then a chemical mechanical polishing (CMP) process is performed on the SOD oxide film 15 using the pad nitride film 14 as a polishing stop film.

Next, referring to FIG. 2, the pad nitride film 14 is removed by performing a wet etching process with a phosphoric acid-containing composition for etching, followed by a cleaning process to remove the buffer oxide film 13. Through these processes, a device isolation film 15A is formed in a field region.

However, when the phosphoric acid-containing composition for etching is employed in the wet etching process for removing the pad nitride film 14, the SOD oxide film 15 as well as the pad nitride film 14 become etched due to a decrease in the etch selectivity of the nitride film with respect to the oxide film, and thus it is difficult to control the effective field oxide height (EFH). Accordingly, a sufficient wet etching time for removal of the nitride film cannot be secured, or an additional process must be performed, thus resulting in deterioration of the etching efficiency and causing a change, which may adversely affect the characteristics of the devices produced.

In order to achieve improved etch selectivity of the phosphoric acid-containing composition for etching, compositions for etching in which hydrofluoric acid (HF) or nitric acid (HNO₃) is added to the phosphoric acid have been disclosed, but this rather leads to a bad result in that inhibition of the etch selectivity of the nitride and oxide films may occur. In addition, compositions for etching in which silicate or silicic acid is added to the phosphoric acid have also been disclosed. However, there is a problem in that the silicate or silicic acid causes particles on a substrate, thereby resulting in deterioration of the reliability of the semiconductor device. Therefore, there is a need for a composition for etching with a high selectivity which does not cause the occurrence of particles, and the like, while selectively etching the nitride film with respect to the oxide film.
Patent Literature: KR10-2013-0042273

### SUMMARY

An embodiment of the present invention is directed to providing a composition for etching a silicon nitride film with a high selectivity, which is capable of selectively removing a nitride film while minimizing the etching rate of an oxide film, while also preventing the occurrence of particles, and the like, which adversely affect the characteristics of semiconductor devices. Another embodiment of the present invention is directed to providing a manufacturing method of a semiconductor device using the composition for etching.

To solve the above-mentioned problems, the present invention provides a composition for etching a silicon nitride film comprising: phosphoric acid; metaphosphoric acid; an ammonium salt-based compound; and water.

Further, the present invention provides a manufacturing method of a semiconductor device comprising a step of etching an insulating film with the composition for etching.

### BRIEF DESCRIPTION OF THE DRAWINGS

FIGS. 1 and 2 are process cross-sectional views illustrating a device isolation process of a conventional flash memory device.

FIGS. 3 to 5 are process cross-sectional views illustrating a device isolation process of a flash memory device comprising an etching process using a composition for etching according to an embodiment of the present invention.

FIGS. 6 to 11 are process cross-sectional views illustrating a process of forming a pipe channel of a flash memory device comprising an etching process using a composition for etching according to another embodiment of the present invention.

FIGS. 12 to 13 are process cross-sectional views illustrating a diode forming process of a phase-change memory (PCM) comprising an etching process using a composition for etching according to another embodiment of the present invention.

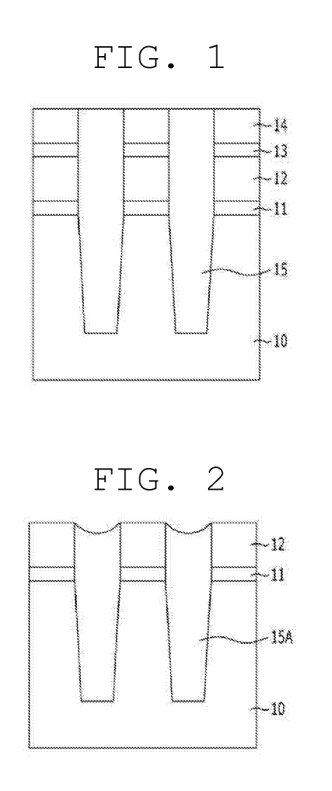

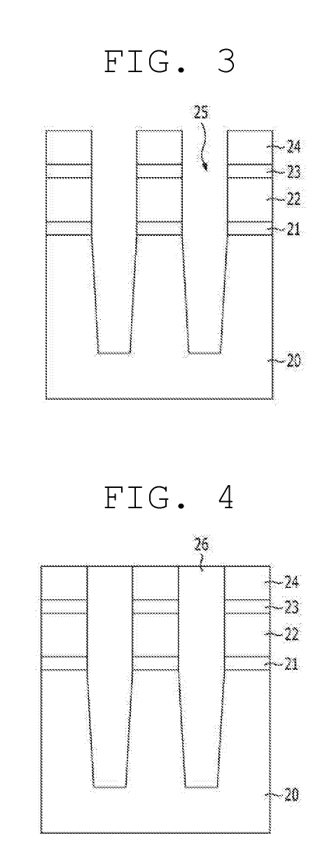

### DETAILED DESCRIPTION OF EMBODIMENTS

When a general phosphoric acid-based composition for etching is applied to the wet etching of a silicon nitride film, there is a problem in that the etching rate is lowered as the etching process proceeds. In consideration of this problem, there have been attempts to employ a composition for etching which comprises both metaphosphoric acid and phosphoric acid, thus resulting in continuous supply of the phosphoric acid in the composition for etching to maintain the etching rate at a constant level, thereby enabling the achievement of uniform and selective etching throughout the entire silicon nitride film.

However, when it is attempted to prepare a composition for etching by directly adding the metaphosphoric acid in a solid form or a powder form to the phosphoric acid, there are problems in that a high temperature and a long preparation time are needed to dissolve the metaphosphoric acid. Therefore, according to the present invention, the above-described problems can be solved by further adding an ammonium salt-based compound in a composition for etching comprising phosphoric acid and metaphosphoric acid.

Hereinafter, the present invention is described in more detail.

1. Composition for Etching Silicon Nitride Film

A composition for etching a silicon nitride film of the present invention (hereinafter referred to as “composition for etching”) comprises phosphoric acid, metaphosphoric acid, an ammonium salt-based compound, and water.

The phosphoric acid may react with silicon nitride to etch the silicon nitride. The silicon nitride may be etched by reacting with phosphoric acid as shown in Reaction Scheme 1 below:

3Si₃N₄+27H₂O+4H₃PO₄→4(NH₄)₃PO₄+9SiO₂H₂O [Reaction Scheme 1]

The content of the phosphoric acid may be 50 to 90% by weight, and preferably 80 to 85% by weight, based on the total weight of the composition for etching. When the phosphoric acid content is less than 70% by weight, the etching capacity of the etching composition for silicon nitride may deteriorate, and when the content of phosphoric acid exceeds 95% by weight, the silicon nitride may be excessively etched, making it difficult to obtain the desired etch profile.

Meanwhile, metaphosphoric acid is a compound having the structure of HPO₃, which has a lower solubility in water than phosphoric acid, and is gradually converted from metaphosphoric acid to phosphoric acid in water, thus serving to facilitate stable etching of the nitride. The content of metaphosphoric acid may be 0.01 to 10% by weight, and preferably 5 to 7% by weight, based on the total weight of the composition for etching. When the content of the metaphosphoric acid is less than 0.01%, the etching rate of a silicon oxide film becomes higher, and the desired profile cannot be obtained due to the lowered selectivity. When the content of the metaphosphoric acid exceeds 10% by weight, the etching of a silicon oxide film is almost nonexistent, but furthermore, the etching rate of a silicon nitride film may also be reduced.

The ammonium salt-based compound is basic, and when the metaphosphoric acid is dissolved in aqueous solvent containing an ammonium salt-based compound, the ammonium salt-based compound can dissolve the metaphosphoric acid well due to its high solubility. When the phosphoric acid is further mixed with the dissolved product, the preparation time can be shortened, thus resulting in increased convenience.

Specifically, the composition may be produced through a method comprising a step of preparing a mixture comprising metaphosphoric acid, an ammonium salt-based compound, and water; and a step of mixing the prepared mixture with phosphoric acid.

Therefore, it is preferable to first dissolve the metaphosphoric acid in the aqueous solvent containing the ammonium salt-based compound, and then mix this with the phosphoric acid.

The ammonium salt-based compound is not particularly limited, but preferably comprises, as a cation, one or more selected from the group consisting of NH4⁺, a primary ammonium ion, a secondary ammonium ion, a tertiary ammonium ion, and a quaternary ammonium ion.

The ammonium salt-based compound is a weak base which is suitable for the phosphoric acid process, and which may be thermally stable for the process which is characterized by heating to a high temperature, without the generation of bubbles.

Specifically, it is more preferable that the ammonium salt-based compound comprise one or more selected from the group consisting of ammonium acetate, ammonium nitrate, ammonium phosphate, tetramethyl ammonium hydroxide (TMAH), and tetraethyl ammonium hydroxide (TEAH).

This ammonium salt-based compound and metaphosphoric acid may be included at a molar ratio of 0.1 to 2:1 to 5, and more preferably, at a molar ratio of 0.5 to 1:2 to 4. When the content of the metaphosphoric acid is below the lower limit, the solubility of metaphosphoric acid is low, so that the process stabilization time may be prolonged when it is incorporated into phosphoric acid, and when the content of metaphosphoric acid exceeds the upper limit, the amount of phosphoric to be added is reduced, and the etching rate of the process silicon nitride film may be deteriorated.

The composition for etching includes water as a solvent. For example, the composition for etching may contain the remaining amount of the composition as water. Specifically, the composition for etching may comprise 50 to 90 wt % of phosphoric acid, 0.01 to 10 wt % of metaphosphoric acid, 0.001 to 5 wt % of an ammonium salt-based compound, and 5 to 40 wt % of water.

In addition, the composition for etching may have an etching rate of nitride films of 50 to 80 Å/min, and an etching rate of oxide films of 0.00 to 3.00 Å/min. More specifically, the etching rate of nitride films may be 60 to 70 Å/min, and the etching rate of oxide films may be 0.01 to 1 Å/min.

Further, the etching composition may have a ratio of the etching rate of a nitride film to the etching rate of an oxide film of above 50. More specifically, the ratio of the nitride film etching rate to the oxide film etching rate may be 50 to 10,000, 100 to 8,000, 100 to 3,000, or 100 to 2,000. Within this range of the ratio of nitride film to oxide film etching rate, etching of an oxide film can be minimized while a nitride film can be selectively removed. In addition, the etching selectivity for a nitride film over an oxide film may be high, and the effective field height (EFH) may be easily controlled by adjusting the etching rate of a nitride film.

The composition for etching may further comprise a residual amount of water as a solvent.

2. Manufacturing Method of Semiconductor Device

The present invention provides a method for manufacture of a semiconductor device using the above-described composition for etching, which is described in detail below.

The manufacturing method for a semiconductor device of the present invention comprises a step of etching an insulating film with the composition for etching described above. Specifically, the composition for etching selectively etches the insulating film in a structure in which the insulating film and an oxide film are mixed.

The nitride film may be a silicon nitride film (for example, a SiN film, a SiON film, or the like).

The oxide film may be a silicon oxide film (for example, an SOD (spin on dielectric) film, HDP (high density plasma) film, thermal oxide film, BPSG (borophosphate silicate glass) film, PSG (phosphosilicate glass) film, BSG (borosilicate glass) film, PSZ (polysilazane) film, FSG (fluorinated silicate glass) film, LP-TEOS (low pressure tetra ethyl ortho silicate) film, PETEOS (plasma enhanced tetra ethyl ortho silicate) film, HTO (high temperature oxide) film, MTO (medium temperature oxide) film, USG (undoped silicate glass) film, SOG (spin on glass) film, APL (advanced planarization layer) film, ALD (atomic layer deposition) film, PE oxide (plasma enhanced oxide) film, O3-TEOS (O3-tetra ethyl ortho silicate) film, and the like.

The etching method of the nitride film is not particularly limited, and may be wet etching (for example, an immersion method or a spraying method).

Further, the etching temperature at which the nitride film is etched is not particularly limited, and may be determined in consideration of other processes and other factors. Specifically, the etching temperature may be 50 to 300° C., and preferably 100 to 200° C.

Since the semiconductor device is manufactured through the process of selectively etching the nitride film using the composition for etching, as described above, it is thereby possible to prevent the occurrence of particles caused by self-binding and reaction of silicon ions, which is a problem in the conventional etching process, thus resulting in the manufacture of a semiconductor device with excellent reliability while ensuring process stability.

Hereinafter, as an example, a case where the above-described composition for etching is employed in a device isolation process of a flash memory device, from among semiconductor devices, is described in detail with reference to the drawings.

Referring to FIG. 3, a tunnel oxide film 21, a polysilicon film 22, a buffer oxide film 23, and a pad nitride film 24 are sequentially formed on a substrate 20. Then, the pad nitride film 24, the buffer oxide film 23, the polysilicon film 22, and the tunnel oxide film 21 are selectively etched through photo and etching processes, thereby exposing a device isolation region of the substrate 20. Subsequently, the exposed substrate 20 is selectively etched using the pad nitride film 24 as a mask to form a trench 25 having a predetermined depth from the surface.

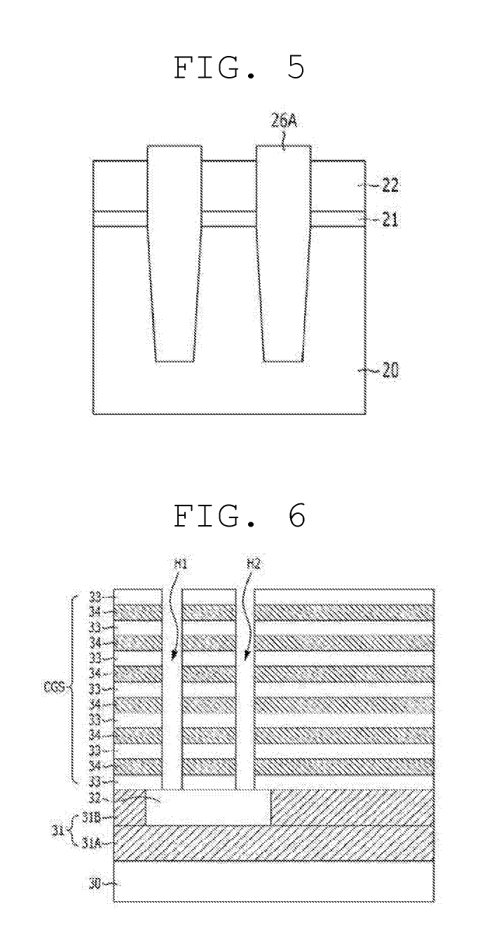

Referring to FIG. 4, an oxide film 26 is formed on the entire surface of the substrate 20 through chemical vapor deposition (CVD), or the like, until gap filling of the trench 25 is achieved. Then, the oxide film 26 is subjected to a chemical mechanical polishing (CMP) process using the pad nitride film 24 as a polishing stop film. Subsequently, a cleaning process is performed using dry etching.

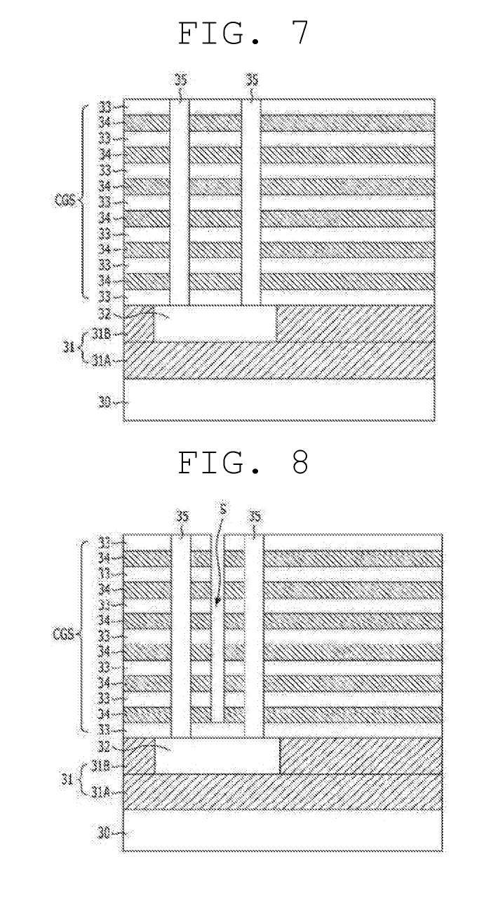

Referring to FIG. 5, the pad nitride film 24 is selectively removed by a wet etching process using the composition for etching according to the present invention, and then the buffer oxide film 23 is removed through a cleaning process. Thus, a device isolation film 26A is formed in a field region. By employing the above-described composition for etching which has a high etch selectivity of the nitride film with respect to the oxide film, as described above, the nitride film can be selectively and completely removed during a sufficient time while minimizing the etching of the oxide film that is used for gap-filling of the shallow trench isolation (STI) patterns. Accordingly, an effective field oxide height (EFH) can be easily controlled, and both the deterioration of electrical characteristics and the occurrence of particles, caused by damage to and etching of the oxide film, can be prevented to achieve improvement of the characteristics of the semiconductor device.

Although the above example has been described for a flash memory device, the high-selectivity composition for etching of the present invention can also be employed for a device isolation process of a DRAM device.

As another example, a case where the above-described composition for etching is employed in a channel forming process of a flash memory device, from among semiconductor devices, is described in detail below with reference to the drawings.

Referring to FIG. 6, a pipe gate electrode film 31 in which a nitride film 32 for forming a pipe channel is embedded is formed on a substrate 30. First and second conductive films 31A and 31B constituting the pipe gate electrode film 31 may comprise, for example, impurity-doped polysilicon. Specifically, the first conductive film 31A is formed on the substrate 30, the nitride film is deposited on the first conductive film 31A, the nitride film is patterned to form the nitride film 32 for forming a pipe channel, and then the second conductive film 31B is formed on the first conductive film 31A exposed by the nitride film 32. These first and second conductive films 31A and 31B form the pipe gate electrode film 31.

Next, a first interlayer insulating film 33 and a first gate electrode film 34 are alternately stacked to form a plurality of memory cells stacked in a vertical direction on the resultant product formed by the above process. Hereinafter, for convenience of explanation, a structure in which the first interlayer insulating film 33 and the first gate electrode film 34 are alternately stacked is referred to as a cell gate structure (CGS). Here, the first interlayer insulating film 33 is provided for isolation among a plurality of stacked memory cells, and may comprise, for example, an oxide film. The first gate electrode film 34 may comprise, for example, impurity-doped polysilicon. Here, a first gate electrode layer 34 formed with six layers is illustrated in FIG. 6, but the present invention is not limited thereto.

Subsequently, the CGS is selectively etched to form a pair of first and second holes H1 and H2 exposing the nitride film 32. The first and second holes H1 and H2 are spaces for channel formation of the memory cell.

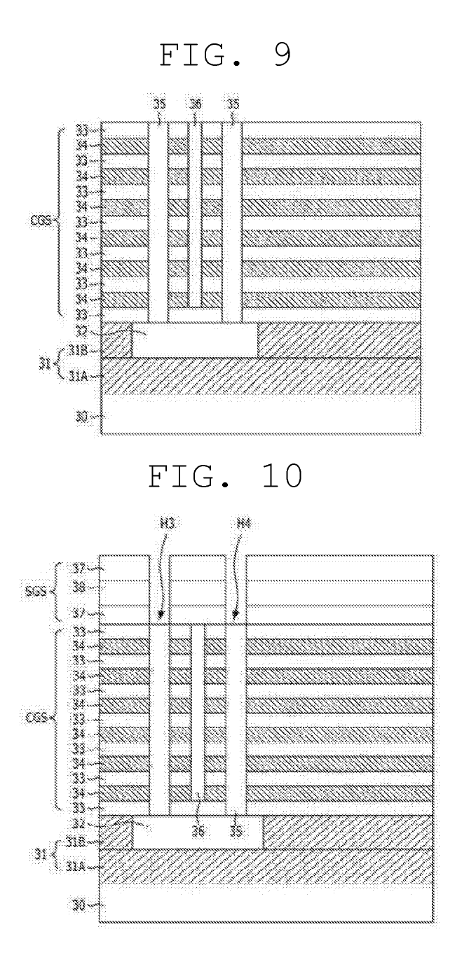

Referring to FIG. 7, a nitride film 35 is formed to be embedded in the first and second holes H1 and H2. This formed nitride film 35 prevents damage that may occur if the first gate electrode film 34 is exposed because of the first and second holes H1 and H2 during a trench forming process (see FIG. 8).

Referring to FIG. 8, the CGS is selectively etched between the pair of first and second holes H1 and H2 so that the plurality of first gate electrode films 34 are separated for each of the first and second holes H1 and H2, thereby forming a trench (S).

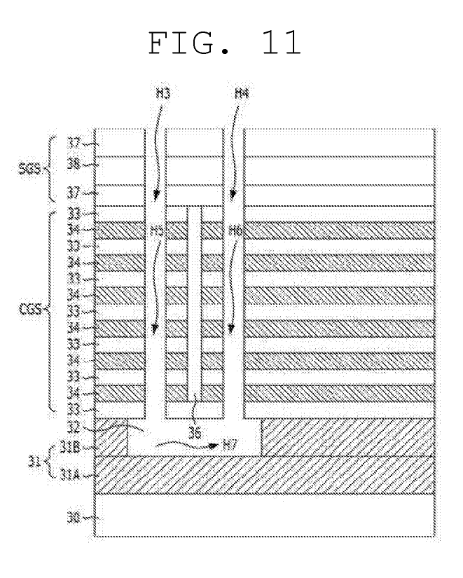

Referring to FIG. 9, a sacrificial film 36 is formed embedded in the trench S.

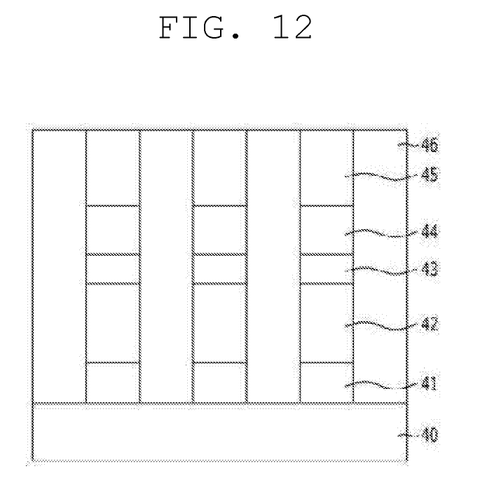

Referring to FIG. 10, a second interlayer insulating film 37, a second gate electrode film 38, and a second interlayer insulating film 37 are sequentially formed on the resultant product formed by the above process to form a selection transistor. Hereinafter, for convenience of explanation, a structure in which the second interlayer insulating film 37, the second gate electrode film 38, and the second interlayer insulating film 37 are stacked is referred to as a selection gate structure (SGS). The second interlayer insulating film 37 may comprise, for example, an oxide film, and the second gate electrode film 38 may comprise, for example, impurity-doped polysilicon.

Subsequently, the selection gate structure SGS is selectively etched to form third and fourth holes H3 and H4 exposing the nitride film 35 embedded in the pair of first and second holes H1 and H2. The third and fourth holes H3 and H4 are regions in which the channel of the selection transistor is to be formed.

Referring to FIG. 11, the nitride film 35 exposed by the third and fourth holes H3 and H4 and the nitride film 32 formed under the nitride film 35 are selectively removed by a wet etching process using the composition for etching according to the present invention. As a result of this process, a pair of cell channel holes H5 and H6 are formed in which channel films of the memory cell are to be formed, and a pipe channel hole H7 is formed under the cell channel holes H5 and H6 to interconnect these cell channel holes H5 and H6. By employing the high-selectivity composition for etching of the present invention as described above, the nitride film can be completely and selectively removed during a sufficient time without loss of the oxide film, thus resulting in accurate formation of the pipe channel without loss of the profile. In addition, it is possible to prevent occurrence of particles, which has been a problem in the conventional process, thereby securing stability and reliability of the process.

Thereafter, a memory device is formed by performing subsequent processes, for example, a floating gate forming process, a control gate forming process, and the like.

As still another example, a case where the above-described composition for etching is employed in a diode forming process of a phase-change memory (PCM) device, from among semiconductor devices, is described in detail below with reference to the drawings.

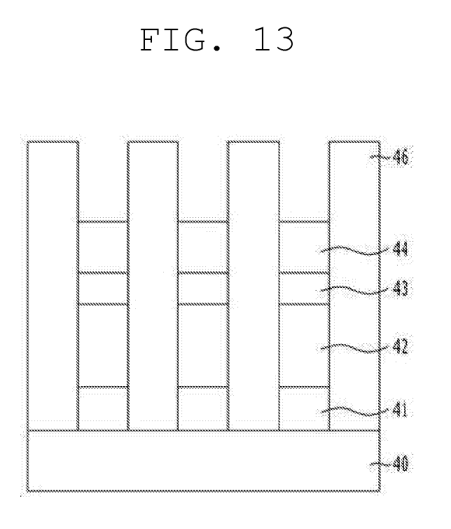

Referring to FIG. 12, an insulating structure having an opening exposing a conductive region 41 is provided on a substrate 40. The conductive region 41 may be, for example, an n+ impurity region. Next, a polysilicon film 42 is formed so as to partially embed the opening, and then impurities are ion-implanted to form a diode. A titanium silicide film 43 is then formed on the polysilicon film 42. The titanium silicide film 43 may be formed by forming a titanium film, followed by heat treatment so as to react with the polysilicon film 42. After that, a titanium nitride film 44 and a nitride film 45 are sequentially formed on the titanium silicide film 43. Next, an oxide film 46 is formed in the isolated space between the formed diodes through performance of a dry etching process using a hard mask, followed by a chemical mechanical polishing (CMP) process, thereby forming the primary structure of the respectively separated lower electrodes.

Referring to FIG. 13, the upper nitride film 45 is selectively removed by performing a wet etching process using the composition for etching according to the present invention on the resultant product formed by the above process. By employing the high-selectivity composition for etching according to the present invention at the time of removing the nitride film as described above, the nitride film can be selectively and completely removed during a sufficient time without loss of the oxide film. In addition, it is possible to prevent both the deterioration of electrical characteristics and occurrence of particles, caused by damage to and etching of the oxide film, thus resulting in improvement of the characteristics of the semiconductor device. Subsequently, titanium is deposited on the space in which the nitride film 45 is removed, thereby forming a lower electrode.

The composition for etching of the present invention can have a high etch selectivity of the nitride film with respect to the oxide film, thereby controlling the etching rate of the oxide film, and thus the effective field oxide height (EFH) can be easily controlled. In addition, the composition for etching of the present invention can prevent the deterioration of electrical characteristics, the occurrence of particles, and the like, caused by damage to and etching of the oxide film when the nitride film is removed, thus resulting in improvement of the reliability of the semiconductor device.

Therefore, the composition for etching of the present invention can be effectively employed to the manufacturing processes of semiconductor devices requiring the selective removal of a nitride film with respect to an oxide film (for example, the device isolation process of a flash memory device, the process of forming a pipe channel of a 3D flash memory device, the diode forming process of a phase-change memory (PCM), and the like), thereby contributing to improvement of the efficiency of the manufacturing process of the semiconductor device.

The present invention is described in detail below through the use of examples; however, it should be understood that the examples are just exemplifications of the present invention, and the present invention is not limited thereto.

### EXAMPLES

### Examples 1 to 7: Etching Compositions According to Embodiments of the Present Invention

Etching compositions having the compositions described in Table 1 below were prepared. Specifically, the ammonium salt-based compound and the metaphosphoric acid were thoroughly dissolved by stirring, and then added to phosphoric acid to prepare an etching composition.

TABLE 1

| Component (wt %) | | Example 1 | Example 2 | Example 3 | Example 4 | Example 5 | Example 6 | Example 7 |
|---|---|---|---|---|---|---|---|---|
| Phosphoric Acid | | 75 | 65 | 92 | 85 | 75 | 80 | 83 |
| Metaphosphoric Acid | | 7 | 5 | 5 | 0.005 | 10 | 6 | 6 |
| Ammonium | Ammonium | — | 1 | — | 0.005 | — | 2 | 0.1 |
| salt-based | Phosphate | | | | | | | |
| compound | TEAH | — | — | 1 | — | 1 | — | — |
| | TMAH | 1 | — | — | — | — | — | — |

| | | | | | | | |
|---|---|---|---|---|---|---|---|
| Water | 17 | 29 | 2 | 14.99 | 14 | 12 | 10.9 |
| Total (wt %) | 100 | 100 | 100 | 100 | 100 | 100 | 100 |

### Comparative Examples 1 to 3

Etching compositions having the compositions described in Table 2 below were prepared in the same way as Example 1.

TABLE 2

| | | Comparative | Comparative | Comparative |
|---|---|---|---|---|
| Component | | Example 1 | Example 2 | Example 3 |
| Phosphoric Acid | | 75 | 80 | 85 |
| Metaphosphoric Acid | | 7 | 5 | — |
| Ammonium | Ammonium | — | — | — |
| salt-based | Phosphate | | | |
| compound | TEAH | — | — | 0.5 |
| | TMAH | — | — | — |

| | | | |
|---|---|---|---|
| Carboxylic acid | 1 | — | — |
| Water | 17 | 15 | 14.5 |
| Total(wt %) | 100 | 100 | 100 |

### Test Example 1: Measurement of Selectivity

Using the etching compositions of Examples 1 to 7 and Comparative Examples 1 to 3, etching of a nitride film and an oxide film was carried out at 165° C., and the etching rates of the nitride and oxide films were measured using an Ellipsometer film thickness measurement device (NANO VIEW, SEMG-1000), the results of which are displayed in Table 3 below.

Specifically, the etching rates displayed in table three are the values obtained by etching a film for 300 seconds and subsequently comparing the film thickness before the etching treatment with the film thickness after etching, and diving the difference of the film thickness by the etching time (in minutes).

TABLE 3

| | | | Nitride Film Etch |
|---|---|---|---|
| | Nitride Film Etch | Oxide Film Etch | Rate/Oxide Film |
| Classification | Rate(Å/min) | Rate (Å/min) | Etch Rate |
| Example 1 | 65.14 | 0.12 | 542.8 |
| Example 2 | 43.78 | 0.03 | 1459.3 |
| Example 3 | 87.56 | 0.75 | 116.7 |
| Example 4 | 72.61 | 1.52 | 47.77 |
| Example 5 | 64.61 | 0.01 | 6461 |
| Example 6 | 66.01 | 0.2 | 330.1 |
| Example 7 | 65.56 | 1.23 | 53.3 |
| Comparative | 72.07 | 2.03 | 35.5 |
| Example 1 | | | |
| Comparative | 70.86 | 2.25 | 31.5 |
| Example 2 | | | |
| Comparative | 71.5 | 2.2 | 32.5 |
| Example 3 | | | |

As can be seen from Table 3, it could be confirmed that the etching compositions of Examples 1 to 7 had remarkably higher etch rates for the nitride film than for the oxide film as compared to Comparative Examples 1 to 3. This supports that the etching composition of the present invention selectively etches nitride films.

### LIST OF REFERENCES

20, 30, 40 substrates
21 a tunnel oxide film
22 a poly silicon film
23 a buffer oxide film
24 a pad nitride film
25 a trench
26 an oxide film
26A a device isolation film
31 a pipe gate electrode film
32, 35 nitride films
36 a sacrificial film
33 a first interlayer insulating film
34 a first gate electrode film
37 a second interlayer insulating film
38 a second gate electrode film
41 a conductive region
42 a poly silicon film
43 a titanium silicide film
44 a titanium nitride film
45 a nitride film
46 an oxide film

What is claimed is:

1. A composition for etching a silicon nitride film comprising:
phosphoric acid;
metaphosphoric acid;
an ammonium salt-based compound; and
water.

2. The composition for etching a silicon nitride film of claim 1, wherein the ammonium salt-based compound comprises, as a cation, one or more selected from the group consisting of NH4⁺, a primary ammonium ion, a secondary ammonium ion, a tertiary ammonium ion, and a quaternary ammonium ion.

3. The composition for etching a silicon nitride film of claim 2, wherein the ammonium salt-based compound comprises one or more selected from the group consisting of ammonium acetate, ammonium nitrate, ammonium phosphate, tetramethyl ammonium hydroxide (TMAH), and tetraethyl ammonium hydroxide (TEAH).

4. The composition for etching a silicon nitride film of claim 1, wherein the content of metaphosphoric acid is 0.01 to 10% by weight.

5. The composition for etching a silicon nitride film of claim 1, wherein the ammonium salt-based compound and the metaphosphoric acid are included in the composition at a molar ratio of 0.1 to 2:1 to 5.

6. The composition for etching a silicon nitride film of claim 1, wherein the method of production of the composition comprises a step of producing a mixture comprising metaphosphoric acid, an ammonium salt-based compound and water; and a step of mixing the produced mixture with phosphoric acid.

7. The composition for etching a silicon nitride film of claim 1, wherein the ratio of the nitride film etch rate to the oxide film etch rate of the etching composition is above 50.

8. A manufacturing method of a semiconductor device comprising:
etching an insulating film with the composition for etching according to claim 1.

9. The manufacturing method of a semiconductor device of claim 5, wherein the insulating film is a nitride film.
